(19) United States
(12) Patent Application Publication
(10) Pub. No.: US 2013/0026554 A1
(43) Pub. Date: Jan. 31, 2013

(54) NAND TYPE FLASH MEMORY FOR INCREASING DATA READ/WRITE RELIABILITY

(71) Applicants: TZUNG HAN LEE, TAIPEI CITY (TW); CHUNG-LIN HUANG, TAOYUAN COUNTY (TW); RON FU CHU, TAIPEI CITY (TW)

(72) Inventors: TZUNG HAN LEE, TAIPEI CITY (TW); CHUNG-LIN HUANG, TAOYUAN COUNTY (TW); RON FU CHU, TAIPEI CITY (TW)

(73) Assignee: INOTERA MEMORIES, INC., TAOYUAN COUNTY (TW)

(21) Appl. No.: 13/196,037

(22) Filed: Aug. 2, 2011

(30) Foreign Application Priority Data
Jul. 29, 2011 (TW) 100126963

(51) Int. Cl. H01L 29/788

(52) U.S. Cl. 257/316; 257/E29.3

(57) ABSTRACT

A NAND type flash memory for increasing data read/write reliability includes a semiconductor substrate unit, a base unit, and a plurality of data storage units. The semiconductor substrate unit includes a semiconductor substrate. The base unit includes a first dielectric layer formed on the semiconductor substrate. The data storage units are adjacent to each other and formed on the first dielectric layer. Each data storage unit includes at least two floating gates formed on the first dielectric layer, a second dielectric layer formed on the first dielectric layer and between the two floating gates, an inter-gate dielectric layer formed on the two floating gates and the second dielectric layer, at least one control gate formed on the inter-gate dielectric layer, and a third dielectric layer formed on the first dielectric layer and surrounding and tightly connecting with the two floating gates, the inter-gate dielectric layer, and the control gate.

### BACKGROUND OF THE INVENTION

1. Field of the Invention

The instant disclosure relates to a NAND type flash memory, and more particularly, to a NAND type flash memory for increasing data read/write reliability.

2. Description of Related Art

A flash Memory, a non-volatile memory, may keep the previously stored written data upon shutdown. In contrast to other storage media, e.g. hard disks, soft disks, magnetic tapes and so on, the flash memory has advantages of small volume, light weight, vibration-proof, low power consumption, and no mechanical movement delay in data access, therefore, are widely used as storage media in consumer electronic devices, embedded systems, or portable computers.

There are two kinds of flash memory: an NOR flash memory and an NAND flash memory. An NOR flash memory is characteristically of low driving voltage, fast access speed, high stability, and are widely applied in portable electrical devices and communication devices such as Personal Computers, mobile phones, personal digital assistances, and set-top boxes. An NAND flash memory is specifically designed as data storage media, for example, a secure digital memory card, a compact flash card, and a memory stick card. Charges move across a floating gate relying on charge coupling which determines a threshold voltage of a transistor under the floating gate upon writing, erasing and reading. In other words, in response to an injection of electrons into the floating gate, the logical status of the floating gate turns from 1 to 0; on the contrary, in response to a move of electrons away from the floating gate, the logical status of the floating gate turns from 0 to 1.

The NAND flash memory contains a plurality of blocks, and each block has a plurality of pages wherein each page is divided into data area and spare area. The data area may contain 2048 bytes that are used for storing data. The spare area may contain 64 bytes that are used for storing error correction code. However, the flash memory may fail to change data update-in-place, in other words, erasing a block including the non-blank page is required prior to writing data into a non-blank page. If a size of written data is over an assigned block, the filled pages in the assigned block may have to be removed to other blocks, and then erasing the assigned block is performed.

There are two kinds of NAND flash memory: a multi-level cell (MLC) NAND flash memory and a single-level cell (SLC) flash memory. For example, a cell of the MLC NAND flash memory includes a floating gate for storing four charge levels indicative of binary values 00, 01, 10, and 11. Therefore, each MLC NAND flash memory cell can store 2 bits at one time. Conversely, each SLC NAND flash memory cell may store only one-bit data in the floating gate, as is less than the MLC NAND flash memory cell. However, the MLC NAND cell shows less data read/write reliability than SLC NAND since the storage charge in the floating gate needs more precise control and tighter distribution in a MLC NAND cell than a SLC NAND cell.

### SUMMARY OF THE INVENTION

One aspect of the instant disclosure relates to a NAND type flash memory for increasing data read/write reliability.

One of the embodiments of the instant disclosure provides a NAND type flash memory for increasing data read/write reliability, comprising: a semiconductor substrate unit, a base unit, and a plurality of data storage units. The semiconductor substrate unit includes at least one semiconductor substrate. The base unit includes a first dielectric layer formed on the semiconductor substrate. The data storage units are adjacent to each other and formed on the first dielectric layer by a semiconductor manufacturing process. Each data storage unit includes at least two floating gates formed on the first dielectric layer and separated from each other by a predetermined distance, a second dielectric layer formed on the first dielectric layer and between the two floating gates, at least one inter-gate dielectric layer formed on the two floating gates and the second dielectric layer, at least one control gate formed on the inter-gate dielectric layer, and a third dielectric layer formed on the first dielectric layer and surrounding and tightly connecting with the two floating gates, the inter-gate dielectric layer, and the control gate.

Therefore, each data storage unit includes at least two floating gates, at least one inter-gate dielectric layer, and at least one control gate, thus the NAND type flash memory of the instant disclosure can increase data read/write reliability such as read/write cycle index or usage lifetime.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1 shows a lateral, schematic view of the NAND type flash memory according to the instant disclosure;

FIG. 2 shows a lateral, schematic view of the NAND type flash memory operated in a write mode according to the instant disclosure; and

FIG. 3 shows a lateral, schematic view of the NAND type flash memory operated in an erase mode according to the instant disclosure.

### DETAILED DESCRIPTION OF THE PREFERRED EMBODIMENTS

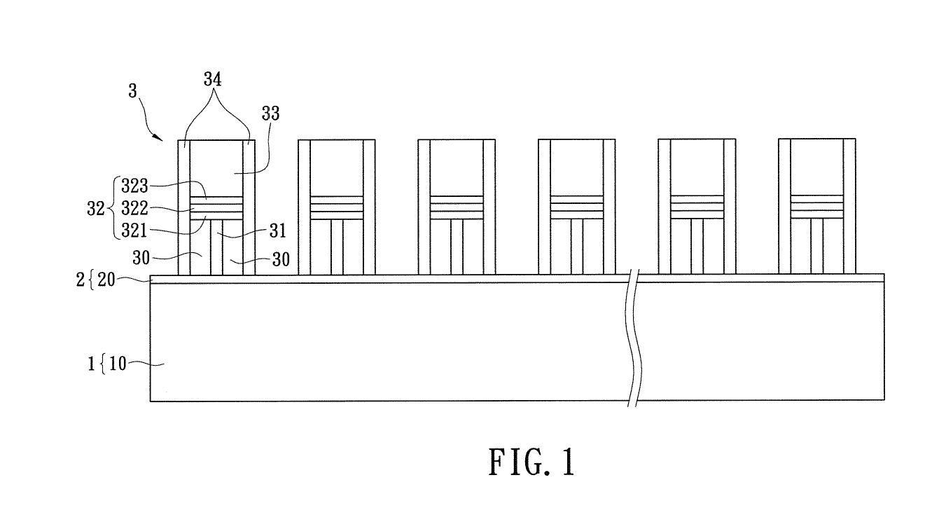

Referring to FIG. 1, where the instant disclosure provides a NAND type flash memory for increasing data read/write reliability, comprising: a semiconductor substrate unit 1, a base unit 2, and a plurality of data storage units 3.

The semiconductor substrate unit 1 includes at least one semiconductor substrate 10. For example, the semiconductor substrate 10 may be a silicon substrate or any type of substrate formed by a semiconductor manufacturing process. In addition, the base unit 2 includes a first dielectric layer 20 formed on the semiconductor substrate 10. For example, the first dielectric layer 20 may be an oxide layer or any type of insulation layer formed by a semiconductor manufacturing process.

Moreover, the data storage units 3 are adjacent to each other and formed on the first dielectric layer 20 by a semiconductor manufacturing process. The data storage units 3 are electrically connected with each other in series to form a NAND string (or row), and the NAND string includes a source zone and a drain zone respectively formed on two sides thereof. In addition, each data storage unit 3 includes at least two floating gates 30, a second dielectric layer 31, at least one inter-gate dielectric layer 32, at least one control gate 33, and a third dielectric layer 34. The two floating gates 30 are formed on the first dielectric layer 20 and separated from each other by a predetermined distance. The second dielectric layer 31 is formed on the first dielectric layer 20 and between the two floating gates 30. The inter-gate dielectric layer 32 is formed on the two floating gates 30 and the second dielectric layer 31. The control gate 33 is formed on the inter-gate dielectric layer 32. The third dielectric layer 34 is formed on the first dielectric layer 20 and surrounds and tightly connects with the two floating gates 30, the inter-gate dielectric layer 32, and the control gate 33. In other words, the two floating gates 30, the inter-gate dielectric layer 32, and the control gate 33 are surrounded by the third dielectric layer 34, and the third dielectric layer 34 simultaneously contacts one part of the peripheral surface of each floating gate 30, the peripheral surface of the inter-gate dielectric layer 32, and the peripheral surface of the control gate 33.

For example, the first dielectric layer 20, the second dielectric layer 31, and the third dielectric layer 34 may be oxide layers or any type of insulation layers formed by a semiconductor manufacturing process. Moreover, the inter-gate dielectric layer 32 may include a first oxide layer 321 formed on the two floating gates 30 and the second dielectric layer 31, a nitride layer 322 formed on the first oxide layer 321, and a second oxide layer 323 formed on the nitride layer 322. Therefore, the inter-gate dielectric layer 32 can be formed as an ONO layer. In addition, each floating gate 30 can be covered by the first dielectric layer 20, the second dielectric layer 31, the third dielectric layer 34, and the inter-gate dielectric layer 32 at the same time. The bottom surface and the peripheral surface of the control gate 33 can be respectively covered by the inter-gate dielectric layer 32 and the third dielectric layer 34, and the top surface of the control gate 33 can be exposed from the third dielectric layer 34.

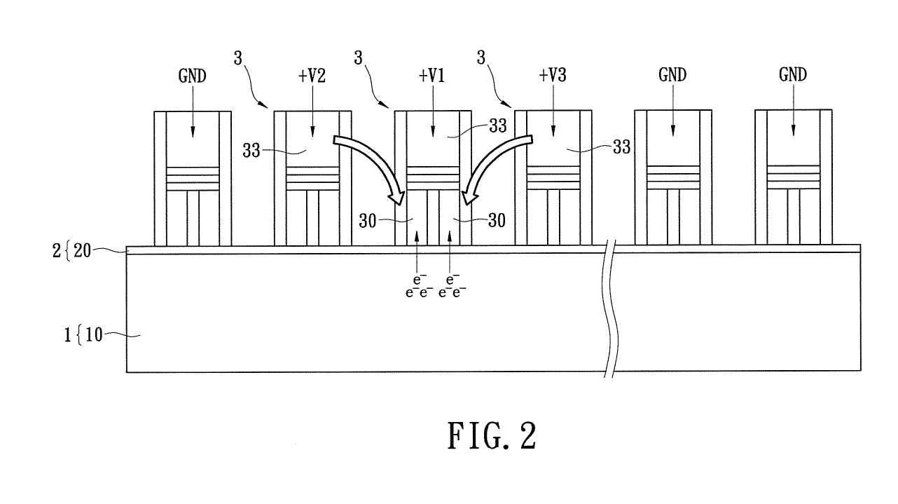

Referring to FIG. 2, when a positive voltage (+V1) is provided to the control gate 33 of a predetermined data storage unit 3, many negative electrons (e−) can be moved from the semiconductor substrate 10 into the two floating gates 30 of the predetermined data storage unit 3 through the first dielectric layer 20, in order to write data into the NAND type flash memory. At the same time, when two positive voltages (+V2, +V3) are provided to the two control gates 33 of another two adjacent data storage units 3 (the other data storage units 3 are connected to grounding (GND)), the two control gates 33 of another two adjacent data storage units 3 as two assist gates are respectively electrically coupled with the two floating gates 30 of the predetermined data storage unit 3. Therefore, the two floating gates 30 of each of the data storage units 3 or any data storage unit 3 can respectively electrically couple with the two control gates 33 of two adjacent data storage units 3 (shown as the two arrows from two control gates 33 to the two floating gates 30 in FIG. 2)

In other words, the positive voltage (+V1) can be provided to the control gate 33 of the predetermined data storage unit 3, thus the control gate 33 of the predetermined data storage unit 3 can directly electrically couple with the two corresponding floating gates 30 of the predetermined data storage unit 3. In addition, the two positive voltages (+V2, +V3) can be provided to the two control gates 33 of the two adjacent data storage units 3, thus the two control gates 33 of the two adjacent data storage units 3 can respectively electrically couple with the two floating gates 30 of the predetermined data storage unit 3.

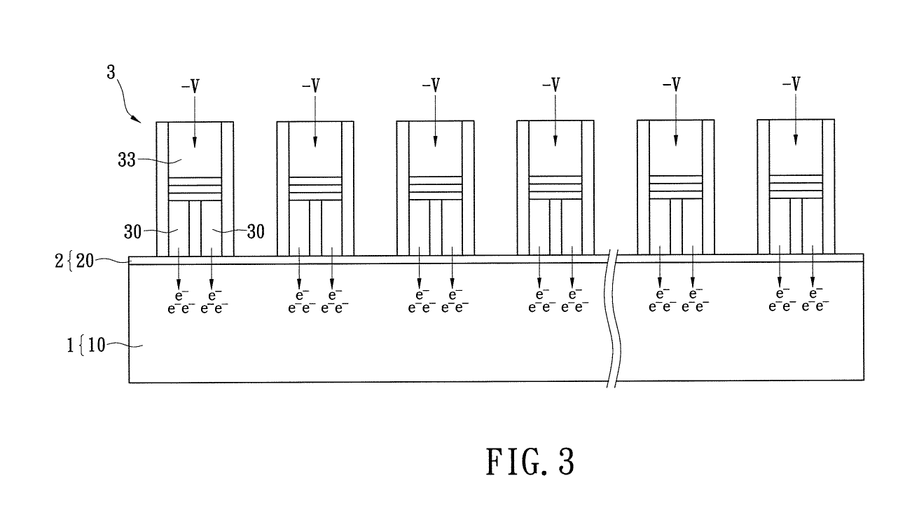

Referring to FIG. 3, when the negative voltage (−V) is provided to the control gate 33 of each data storage unit 3, many negative electrons (e−) can be moved from the two floating gates 30 of each data storage unit 3 into the semiconductor substrate 10 into through the first dielectric layer 20, in order to erase data from the NAND type flash memory.

Because of the way the layers stack in the stacked gates memory cell, the IGI layer (inter-gate insulator layer) is sandwiched at least between the floating gate electrode (FG) and the control gate electrode (CG). The inter-gate insulator (IGI) layer typically contains a series of different dielectric materials. The classical combination is that of silicon Oxide, silicon Nitride and again silicon Oxide in the recited order, hence the name, ONO.

The insulatively-isolated floating gate (FG) of a stacked gates cell is intended to store a relatively precise amount of charge and to retain that stored amount of charge even when external power is turned off. The amount of charge stored by the FG can be used to define the data state of the memory cell. The state of the memory cell can be altered by moving additional charge into the FG for representing a first data state and by removing charge from the FG for representing another data state. Different mechanisms may be used for injecting charge into or removing charge from the FG, including hot carrier injection and/or Fowler-Nordheim tunneling.

The charged or uncharged state of the floating gate (FG) can be sensed by applying a cell-read voltage to the control gate (CG), where the cell-read voltage is selected to cause a first magnitude of current conduction between the drain and source regions of the cell when the floating gate (FG) is in a first programmed state and to cause no or a different magnitude of IDS to flow when the floating gate (FG) is in another programmed state. Some devices store multiple data bits per cell, where each of different amounts of charge trapped within the FG represents a different multi-bit pattern. During data write and/or erase operations, it is common to apply relatively large voltages to the control gate (CG) so as to induce Fowler-Nordheim tunneling and/or other charge transport mechanisms between the floating gate (FG) and one or more other electrode regions within the memory cell (including source and/or drain regions).

It is important, for purposes of carrying out the various read and write/erase operations of floating gate type memory cells (e.g., stacked gate cells), to establish an appropriate pattern of electric field intensities through the insulators, especially the ones that surround the charge-storing, floating gate (FG). These electric fields (E-fields) may be established by generating correspondingly appropriate voltages between the control gate (CG), the drain, the source and/or substrate regions of the memory cell. The electric field intensity in dielectric insulators is usually a function of voltage difference (V) divided by dielectric thickness (d) and multiplied by dielectric constant (E=kV/d). Capacitive coupling is a function of plate area divided by dielectric thickness (C=f(kA/d)). In order to get consistent results from one mass produced device to the next, it is important to maintain precise control, during mass production, over the per-cell plate-area (A), the dielectric thickness (d) and the dielectric constant (k) of the various insulators which surround the FG of each cell so that same results will occur in one device and the next for a given control gate voltage. Stated otherwise, consistently same capacitive coupling should occur, without excessive leakage, from one mass produced device to the next as measured between the CG, the FG, the source, the drain and the substrate.

In conclusion, each data storage unit includes at least two floating gates, at least one inter-gate dielectric layer, and at least one control gate, thus the NAND type flash memory of the instant disclosure can increase data read/write reliability such as read/write cycle index or usage lifetime.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

What is claimed is:

1. A NAND type flash memory for increasing data read/write reliability, comprising:
a semiconductor substrate unit including at least one semiconductor substrate;
a base unit including a first dielectric layer formed on the semiconductor substrate; and
a plurality of data storage units adjacent to each other and formed on the first dielectric layer by a semiconductor manufacturing process, wherein each data storage unit includes at least two floating gates formed on the first dielectric layer and separated from each other by a predetermined distance, a second dielectric layer formed on the first dielectric layer and between the two floating gates, at least one inter-gate dielectric layer formed on the two floating gates and the second dielectric layer, at least one control gate formed on the inter-gate dielectric layer, and a third dielectric layer formed on the first dielectric layer and surrounding and tightly connecting with the two floating gates, the inter-gate dielectric layer, and the control gate.

2. The NAND type flash memory of claim 1, wherein the semiconductor substrate is a silicon substrate, and the first dielectric layer, the second dielectric layer, and the third dielectric layer are oxide layers.

3. The NAND type flash memory of claim 1, wherein the inter-gate dielectric layer includes a first oxide layer formed on the two floating gates and the second dielectric layer, a nitride layer formed on the first oxide layer, and a second oxide layer formed on the nitride layer.

4. The NAND type flash memory of claim 1, wherein each floating gate is covered by the first dielectric layer, the second dielectric layer, the third dielectric layer, and the inter-gate dielectric layer.

5. The NAND type flash memory of claim 1, wherein the bottom surface and the peripheral surface of the control gate are respectively covered by the inter-gate dielectric layer and the third dielectric layer, and the top surface of the control gate is exposed.

6. A NAND type flash memory for increasing data read/write reliability, comprising:
a semiconductor substrate unit including at least one semiconductor substrate;
a base unit including a first dielectric layer formed on the semiconductor substrate; and
a plurality of data storage units adjacent to each other and formed on the first dielectric layer by a semiconductor manufacturing process, wherein each data storage unit includes at least two floating gates formed on the first dielectric layer and separated from each other by a predetermined distance, a second dielectric layer formed on the first dielectric layer and between the two floating gates, at least one inter-gate dielectric layer formed on the two floating gates and the second dielectric layer, at least one control gate formed on the inter-gate dielectric layer, and a third dielectric layer formed on the first dielectric layer and surrounding and tightly connecting with the two floating gates, the inter-gate dielectric layer, and the control gate, wherein the two floating gates of each data storage unit are respectively electrically coupled with two control gates of two adjacent data storage units.

7. The NAND type flash memory of claim 6, wherein the semiconductor substrate is a silicon substrate, and the first dielectric layer, the second dielectric layer, and the third dielectric layer are oxide layers.

8. The NAND type flash memory of claim 6, wherein the inter-gate dielectric layer includes a first oxide layer formed on the two floating gates and the second dielectric layer, a nitride layer formed on the first oxide layer, and a second oxide layer formed on the nitride layer.

9. The NAND type flash memory of claim 6, wherein each floating gate is covered by the first dielectric layer, the second dielectric layer, the third dielectric layer, and the inter-gate dielectric layer.

10. The NAND type flash memory of claim 6, wherein the bottom surface and the peripheral surface of the control gate are respectively covered by the inter-gate dielectric layer and the third dielectric layer, and the top surface of the control gate is exposed.
